(19) United States
(12) Patent Application Publication
(10) Pub. No.: US 2002/0162702 A1
(43) Pub. Date: Nov. 7, 2002

(54) Speaker supporting system

(76) Inventor: Doug Kramer, The Woodlands, TX (US)

Correspondence Address: CONLEY ROSE & TAYON, P.C., P. O. BOX 3267, HOUSTON, TX, 77253-3267, US

(21) Appl. No.: 09/849,790

(22) Filed: May 4, 2001

(51) Int. Cl. H05K 5/00

(52) U.S. Cl. 181/150; 181/148

(57) ABSTRACT

An embodiment of the invention comprises an apparatus for mounting a speaker to a wall, comprising a wall plate covering the in-wall electrical box and having an opening and a support member being coupled to the wall plate and capable of coupling to the speaker.

### CROSS-REFERENCE TO RELATED APPLICATIONS

Not Applicable.

### STATEMENT REGARDING FEDERALLY SPONSORED RESEARCH OR DEVELOPMENT

Not Applicable.

### BACKGROUND OF THE INVENTION

1. Field of the Invention

The present invention relates generally to a speaker support assembly. More particularly, the present invention relates to a wall plate having or using a support device to support a speaker.

2. Description of the Related Art

Most new homes and apartments now include a speaker pre-wire configuration for installation of surround sound-home stereo and theatre. The pre-wire usually stems from the central location where the entertainment center is likely to be positioned. A speaker wire then branches off through the walls terminating at an in-wall electrical box, typically hidden by a blank wall plate. Wall plates of many types are known in the art. For example, Leviton Manufacturing produces wall plates, some having various openings therein for switches and knobs and some with louvres therein. Such wall plates are made from a variety of material, including plastic, stainless steel, high abuse nylon, chrome, aluminum, and brass. Even with the pre-wire configuration, remote speakers must still be installed.

Presently, there are very few options for installation of a remote speaker that do not require a professional installer. Many methods and speaker mounting systems are well known. Most of these prior art speaker mounting systems use some type of frame, shelf, or arm mounted to a wall in a secure location, preferably mounted to the studs in the wall. However, prior art speaker mounting systems have many problems, including costs, aesthetics, and simplicity. For example, for a full surround sound system, purchase and installation of a prior art system may cost $500-$600. Additionally, prior art systems do not account for aesthetics when transitioning the wire from the original pre-wire location to the newly installed brackets, thus requiring the wire to be run along the ceiling or baseboard, and eventually against the wall and to the speaker. This problem clearly detracts from the goal of hidden, in-wall pre-wire.

Another problem with prior art systems is that such systems require additional wall penetrations, requiring that new holes be cut or drilled into the wall and requiring that careful attention be paid to assure alignment, secureness, and coordination with the source's speaker wire. The present invention solves these problems by providing an inexpensive, aesthetically pleasing, and simply speaker support system.

### SUMMARY OF THE INVENTION

An embodiment of the present invention features an apparatus for mounting a speaker to a wall, comprising a wall plate having a first opening therethrough and a support member having a first end and a second end and extending through the first opening, the first end being coupled to the wall plate, and the second end being capable of supporting the speaker. The present invention comprises a combination of features and advantages which enable it to overcome various problems of prior devices. The various characteristics described above, as well as other features, will be readily apparent to those skilled in the art upon reading the following detailed description of embodiments of the invention, and by referring to the accompanying drawings.

### BRIEF DESCRIPTION OF THE DRAWINGS

For a more detailed description of embodiments of the present invention, reference will now be made to the accompanying drawings, wherein:

FIG. 1A is a front view of an embodiment of the invention;

FIG. 1B is a front view of another wall plate embodiment of the invention;

FIG. 1C is a front view of yet another wall plate embodiment of the invention;

FIG. 1D is a front view of yet another wall plate embodiment of the invention;

FIG. 2 is the rear view of the embodiment illustrated in FIG. 1A;

FIG. 3A is a side view of the embodiment illustrated in FIG. 1A;

FIG. 3B is a side view of the embodiment illustrated in FIG. 1A, further illustrating the embodiment coupled to a wall and also to a speaker;

FIG. 4 is a side view of an alternative embodiment of the support portion of an embodiment of the invention;

FIG. 5 is a side view of an embodiment of a directional assembly in accordance with an embodiment of the invention;

FIG. 6 is a perspective view of another alternative embodiment of the support portion of an embodiment the invention;

FIG. 7 is a perspective view of another alternative embodiment of the support portion of an embodiment the invention;

FIG. 8 is a perspective view of a speaker set forth in an X, Y, Z coordinate system; and

FIG. 9 is a perspective view of another alternative embodiment of the support portion of the invention.

### DETAILED DESCRIPTION OF THE PREFERRED EMBODIMENTS

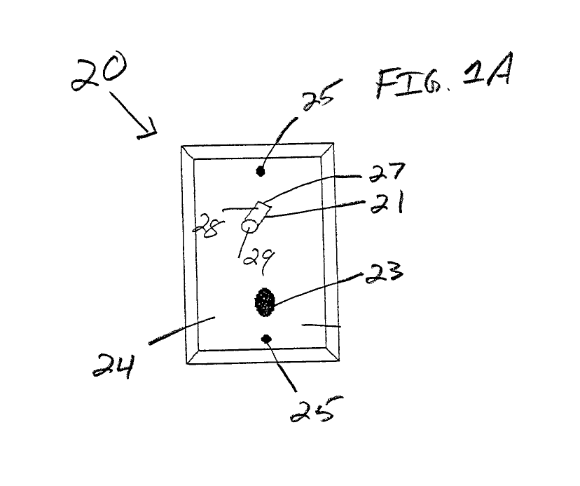

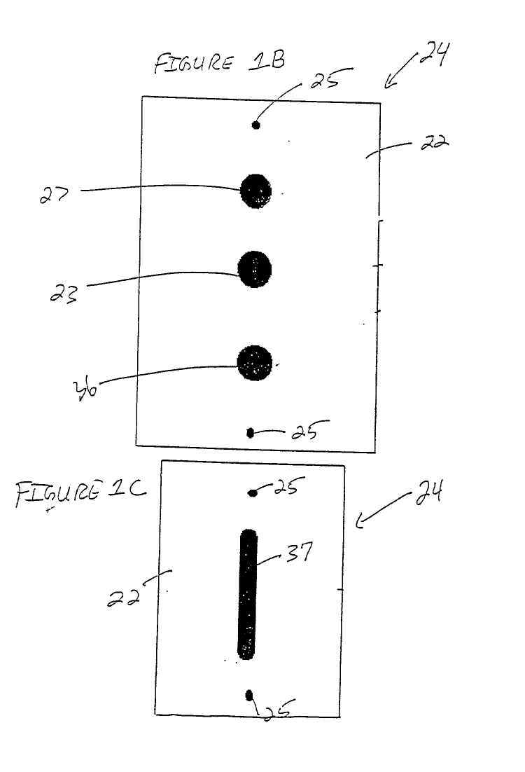

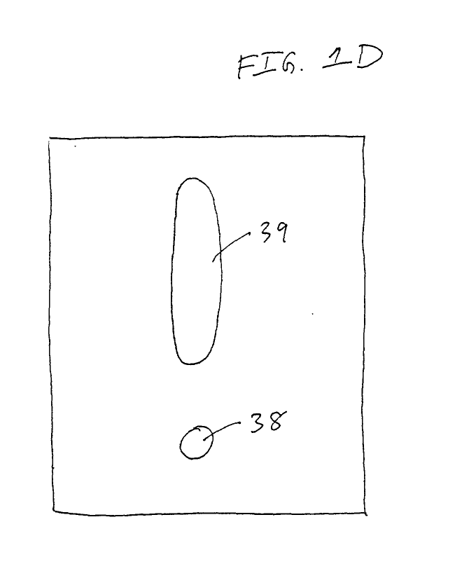

FIGS. 1A and 2 show an embodiment of the wall plate speaker support apparatus 20. Apparatus 20 comprises support member 21 and wall plate 24. Wall plate 24 has a front 22, a back 26, and at least one opening 27. Wall plate 24 can be made from metal, plastic, wood, nylon, or other like materials. Opening 27 preferably has its center along the vertical center of wall plate 24, but of course may be positioned elsewhere. In one embodiment, support 21 extends through wall plate 24 via opening 27. Opening 27 is sized so that support 21 and wire 31 (see FIG. 3B) are able to simultaneously pass through opening 27 in wall plate 24.

Apparatus 20 may also have another opening 23 that can allow wire 31 (FIG. 3B) or support 21 to extend from back 26, through wall plate 24, and couple with speaker 30. Thus, wire 31 and support 21 may extend through different openings.

In another embodiment, support 21 is coupled to front 22 via an adhesive, including but not limited to glue or cement, or via a weld or solder. Use of the term “coupled” herein means a direct or indirect connection that can be permanent or releasable. Thus, if a first device “couples” to a second device, that connection may be through a direct connection, or through an indirect connection via other devices and/or connections. Additionally, support 21 and wall plate 24 can be produced from a unitary mold, cast, or plasmature. In these embodiments, wire 31 can pass through opening 23.

In FIG. 1A, support 21 is an elongated member, such as a bolt, having first and second 20 ends 28, 29 respectively. First end 28 is capable of coupling to wall plate 24. Second end 29 couples to speaker 30 (see FIG. 3B). Preferably, second end 29 is threaded so as to engage a correspondingly threaded portion of speaker 30. This allows speaker 30 to be readily engaged and disengaged from support 21. Further, the bolt embodiment of support 21 is inexpensive and easily installed.

Still referring to FIGS. 1A and 2, one or more holes 25 in wall plate 24 allow support 21 to be mounted to the wall. Typically this is accomplished by screws, bolts, or other support devices passing through openings 25 and into a stud or other wall member. Mounting may also be accomplished by engaging the support device with the sheet rock or other wall surface, depending on the weight of the speaker.

Turning to FIG. 1B, in another embodiment yet another opening 36 is provided for passage of wire 31 and/or support 21 through wall plate 24. This can help, for example, the installer of the speaker 30 to adjust the positioning of support 21 and/or wire 31 to assure the best access to the coupling of support 21 and/or wire 31 to speaker 30. Further, opening 36 allows support 21 and speaker 30 to be adjusted relative to wall plate 24. It must be noted that openings 23, 27 and 36 may have the same or different diameters and/or the same or different shape without deporting from the spirit of the invention.

Turning to FIG. 1C, yet another embodiment of wall plate 24 is shown. There, the opening through which support 21 and/or wire 31 can pass is an elongated opening 37. Preferably, opening 37 is located on the central vertical axis of plate 22, but may be located elsewhere. This embodiment also allows the installer flexibility in positioning the support 21 and/or wire 31. Although opening 37 is preferably elongated, it may take other shapes. Still further, apparatus 20 may comprise a combination of shapes for the openings through which support 21 and/or wire 31 pass. For example, as shown in FIG. 1D, an embodiment of apparatus 20 may comprise a round opening 38 and an elongated opening 39.

Turning next to FIGS. 3A and 3B, there are shown side views of apparatus 20. FIG. 3A shows a stand alone side view of apparatus 20 with support 21 extending from front 22 of wall plate 24. FIG. 3B shows apparatus 20 coupled to wall 32 and speaker 30. As depicted in the embodiment illustrated in FIG. 3B, wire 31 passes through opening 23 and couples with speaker 30. It must be noted, however, that FIG. 3B does not limit the breadth of the present invention, as wire 31 could pass through the same opening as support 21, or wire 31 could pass through opening 27 while support 21 could pass through opening 23. As shown from FIG. 3B, wire 31 is virtually hidden from all views. This should be contrasted with the prior art where wire 31 may run several feet along a wall before connecting with speaker 30.

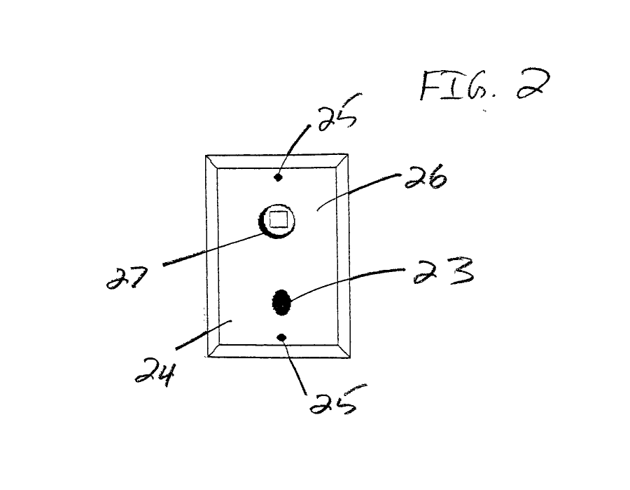

Turning now to FIG. 4, a side view of a hook embodiment 40 of the support is shown. Hook 40 has a first end 41 and a second end 42. In the embodiment shown, first end 41 would be coupled to wall plate 24 at, preferably, first opening 27, but could be coupled to any opening. On the other hand, second end 42 would couple with speaker 30. Hook 40 can pass through an opening in wall plate 24 or can be coupled to wall plate 24 via an adhesive, weld, or solder. Hook 40 and wall plate 24 can also be made from the same unitary mold, cast, or plasmature as wall plate 24. It should be understood that hook 40 is not limited to the precise configuration shown in FIG. 4 but instead encompasses other configurations that do not depart from the spirit of the invention.

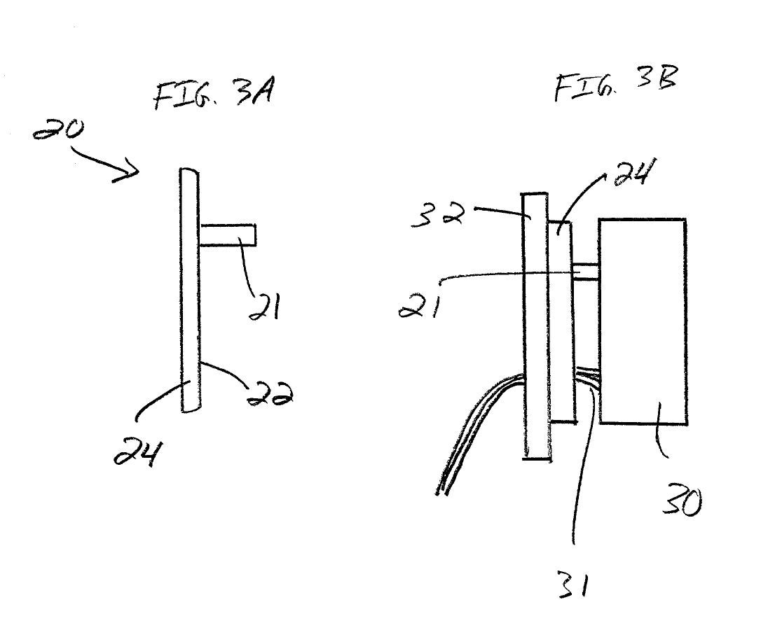

Referring now to FIG. 5, a directional assembly 50 is shown. Directional assembly 50 comprises first arm 51 having ends 54 and 55, second arm 52 having ends 56 and 57, and directional member 53. Directional member 53 can be disposed between arms 51 and 52. In such embodiment, ends 55 and 57 couple to directional member 53 while end 54 of arm 51 is coupled to wall plate 24 and end 56 of arm 52 is coupled to speaker 30. Further, directional member 53 can be located anywhere along apparatus 20. Directional assembly 50 may also comprise multiple directional members 53 and multiple support members or arms.

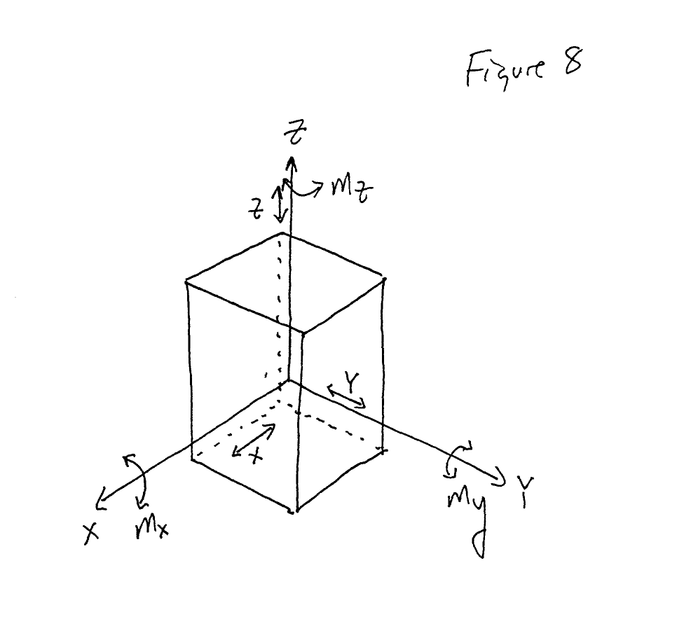

In the preferred embodiment, directional member 53 allows speaker 30 to translate and rotate through the six degrees of freedom illustrated in FIG. 8. Specifically, FIG. 8 illustrates directional member 53 allowing speaker 30 to translate in the directions of Arrows X, Y, Z and also allowing speaker 30 to rotate in the directions of Arrows Mₓ, M_{y}, M_{z}. Examples of directional members 53 include, but are not limited to, swivels and ball and socket joints.

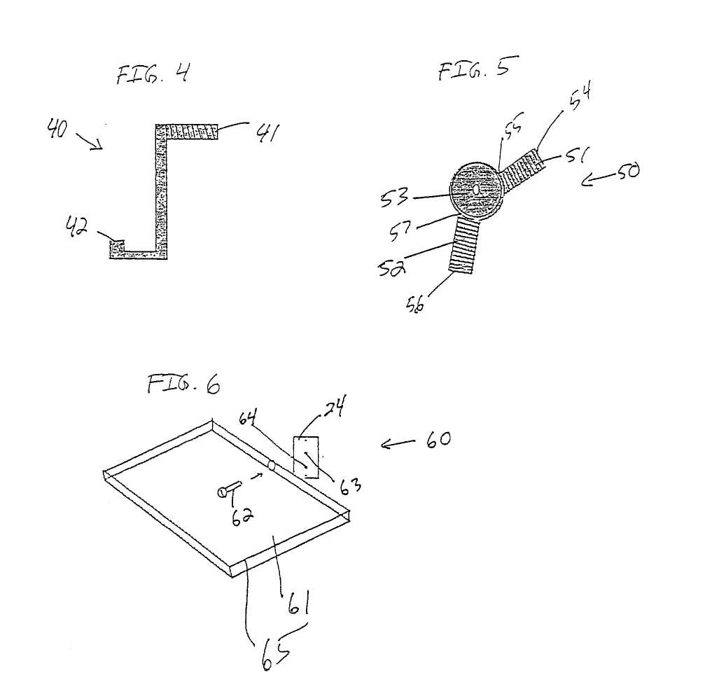

Referring now to FIG. 6, an alternative embodiment of the support of the invention is shown. Apparatus 60 includes shelf member 61 coupled to wall plate 64 by connector 62. Shelf member 61 may also be made from the same unitary mold, cast, or plastmature as wall plate 64.

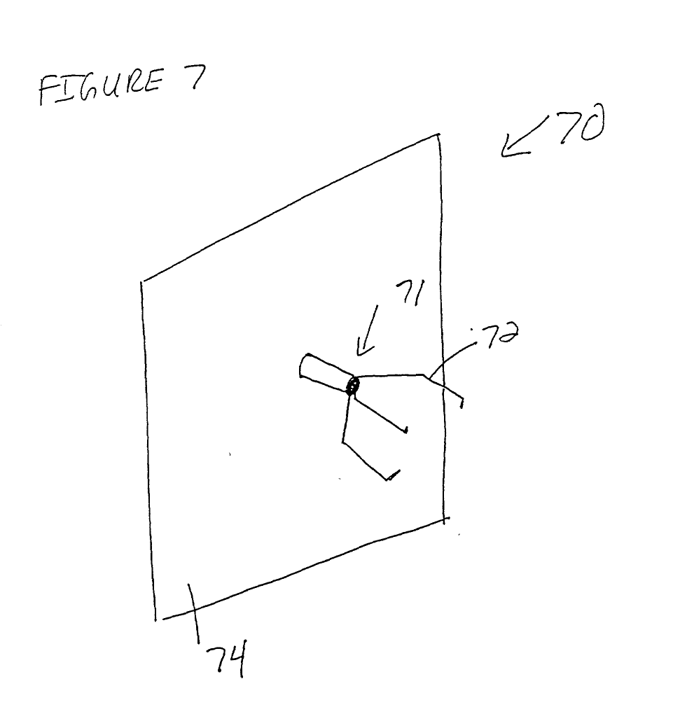

Turning now to FIG. 7, another embodiment of the support of the invention is shown. There, apparatus 70 comprises holder 71 and wall plate 74. Holder 71 is coupled to wall plate 74 and extend therefrom. Holder 71 may also be made from the same unitary mold, cast, or plastmature as wall plate 74. Holders 71 can include two or more gripping members 72, which are preferably biased, so as to grip and support a speaker that is placed between gripping members 72. Preferably holder 71 comprises three gripping members 72, one contacting each side of speaker 30 and the third contacting the bottom or rear of speaker 30.

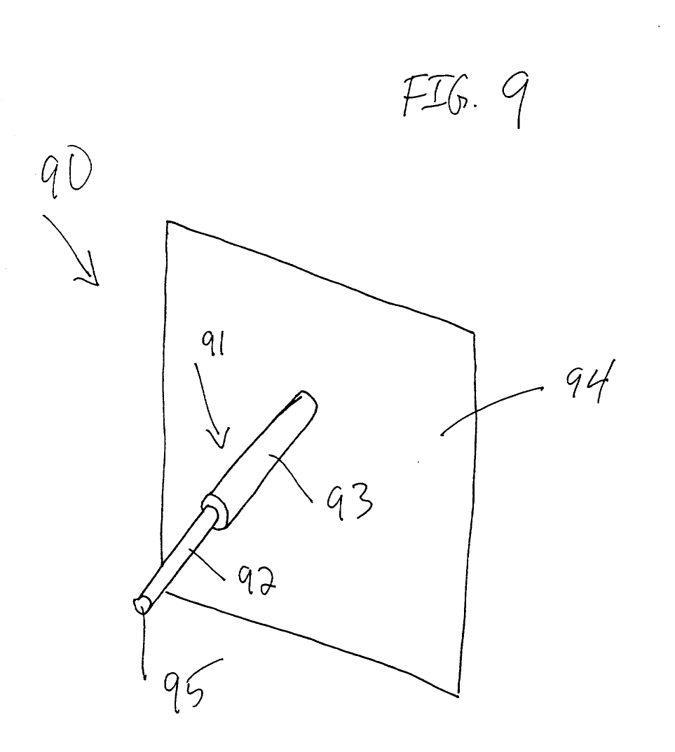

Referring next to FIG. 9, yet another embodiment of the support is shown. In this embodiment apparatus 90 comprises at least one telescopic member 91, which itself comprises inner and outer telescopic portions 92, 93 respectively. End 95 of inner portion 92 preferably couples to speaker 30, possibly via a threading engagement for example. Telescopic member 91 can be coupled to wall plate 94 in any manner, including all ways described herein. Telescopic member 91 allows for adjustment and movement of speaker 30. Telescopic member 91 may telescope in any direction, including perpendicular to wall plate 94 (FIG. 9) or parallel to the face of the wall plate (not shown). Further, telescopic member 91 can be used alone or in combination with directional members 53.

It should be noted that the various embodiments of openings for the support members and/or wire, the support members, and directional member can be used in any combination. Moreover, while preferred embodiments of this invention have been shown and described, modifications thereof can be made by one skilled in the art without departing from the spirit or teaching of this invention. The embodiments described herein are exemplary only and are not limiting. Many variations and modifications of the system and apparatus are possible and are within the scope of the invention. Accordingly, the scope of protection is not limited to the embodiments described herein, but is only limited by the claims which follow, the scope of which shall include all equivalents of the subject matter of the claims.

What is claimed is:

1. An apparatus for mounting a speaker to a wall, comprising:
a wall plate having a first opening; and
a support member having a first end and a second end, said support member extending through said opening, said first end being coupled to said wall plate, and said second end being capable of coupling to the speaker.

2. The apparatus of claim 1, wherein said support comprises a bolt and a nut, said nut threadingly engaged with said bolt to hold said first end to said wall plate.

3. The apparatus of claim 2, wherein said second end of said support is threaded.

4. The apparatus of claim 1, wherein said first opening is sized to also permit wire to extend therethrough.

5. The apparatus of claim 1, wherein said wall plate further has a second opening therethrough.

6. The apparatus of claim 1, further comprising a directional member coupled to said support member.

7. The apparatus of claim 6 wherein said directional member is located proximate to said first end.

8. The apparatus of claim 6 wherein said directional member permits the speaker to be rotated.

9. An apparatus for mounting a speaker to a wall, comprising:
a wall plate being disposed on the wall; and
a support member extending from said wall plate, said support member having at least first and second portions, said first and second portions being coupled.

10. The apparatus of claim 9, wherein said first portion is telescopingly engaged with said second portion.

11. The apparatus of claim 10, further comprising a directional member disposed on said first portion.

12. The apparatus of claim 10, further comprising a directional member disposed on said second portion.

13. An apparatus for mounting a speaker to a wall, comprising:
a wall plate disposed on the wall;
a telescoping support member coupled to said wall plate; and
a ball joint disposed on said telescoping member.

14. A system for mounting a speaker to an in-wall electrical box, comprising:
a wall plate affixed to the wall and covering the in-wall electrical box; and
an elongated member having a wall end and a speaker end, said wall end extending from said wall plate.

15. A system for mounting a speaker to an in-wall electrical box, comprising:
a wall plate affixed to the wall and covering the in-wall electrical box, said wall plate having a first opening; and
a support member coupled to said wall plate.

16. The apparatus of claim 15, wherein said support member comprises a holder.

17. The apparatus of claim 15, wherein said support member comprises a shelf member.

18. The apparatus of claim 15, wherein said support member comprises a hook member.

19. The apparatus of claim 15, wherein said support member comprises a nut and bolt.

20. The apparatus of claim 15, wherein said support member comprises telescopic member.

21. The apparatus of claim 15, wherein said wall plate further has a second opening.

22. The apparatus of claim 21, wherein said wall plate further has a third opening.

23. The apparatus of claim 16, wherein said holder comprises three gripping members.

24. The apparatus of claim 15, further comprising a directional member coupled to said support member.

25. The apparatus of claim 15 wherein said wall plate and said support member are unitary.

26. An apparatus for mounting a speaker to a wall, comprising:
a wall plate coupled to the wall and covering the in-wall electrical box; and
a means for supporting the speaker, said means for supporting being coupled to said wall plate.

27. The apparatus of claim 26 wherein said wall plate has an elongated opening.

28. The apparatus of claim 27 wherein said wall plate has a second opening.

29. The apparatus of claim 27 wherein said means comprises a shelf member.

30. The apparatus of claim 27 wherein said means comprises a nut and bolt.

31. The apparatus of claim 27 wherein said means comprises a holder.

32. The apparatus of claim 27 wherein said means comprises a hook.

33. The apparatus of claim 26 wherein said wall plate has three openings.

34. A method for mounting a speaker, comprising:
covering the in-wall electrical box with a wall plate having an opening; and
extending a support member from the wall plate, the support member coupling to the speaker.

35. The method of claim 34 wherein the wall plate and support member are unitary.
